(19) United States
(12) Patent Application Publication
(10) Pub. No.: US 2018/0340682 A1
(43) Pub. Date: Nov. 29, 2018

(54) LIGHTING DEVICE MODULES

(71) Applicant: OSRAM SYLVANIA Inc., Wilmington, MA (US)

(72) Inventors: Thomas Tessnow, Weare, NH (US); Chad Ice, Nashville, TN (US); Vernon Price, Hendersonville, TN (US); Ryan Winczewski, Hendersonville, TN (US); Dwayne Mott, Nashville, TN (US)

(21) Appl. No.: 15/988,074

(22) Filed: May 24, 2018

Related U.S. Application Data
(60) Provisional application No. 62/510,340, filed on May 24, 2017.

(51) Int. Cl. F21V 29/76; F21V 29/75; H05K 1/02

(52) U.S. Cl. CPC F21V 29/763; H05K 2201/10106; H05K 1/0206; F21V 29/75

(57) ABSTRACT

A light weight lighting module and devices including the same are disclosed. The module includes a printed circuit board with a first side and a second side, each including a conductive layer disposed thereon. The printed circuit board also includes thermal vias disposed therein, in thermal contact with the conductive layers on the first and second sides. One or more light sources are attached to the first side of the printed circuit board, such as high power light emitting diodes or laser light sources. A heat sink is attached to the second side of the printed circuit board. The light source(s) and heat sink are in thermal contact with the thermal vias of the printed circuit board so that thermal energy from the light source(s) can be transferred to the heat sink. The thermally-conductive layers and heat sink remain electrically isolated from the light source(s).

### CROSS-REFERENCE TO RELATED APPLICATION

The present application claims the benefit of priority of U.S. Provisional Patent Application No. 62/510,340, filed May 24, 2017, the entire contents of which are hereby incorporated by reference.

### TECHNICAL FIELD

The present invention relates to lighting devices, and more specifically, to lighting device modules.

### BACKGROUND

Lighting devices are commonly used in automotive applications to illuminate internal and external areas of an automobile. Devices, such as headlights, taillights, brake lights, and turn signals, allow drivers to see the road in front of them and visually communicate with other drivers. Such devices include lamps that generate light and lens/reflectors to beam shape that light in a particular light distribution pattern that enables use of the vehicle. Automobiles also typically include interior lights such as reading lights, map lights, access lights, and the like, to allow drivers and passengers to safely enter and exit interior spaces of the automobile during times of low ambient light or otherwise use the vehicle under such conditions.

### SUMMARY

Automotive lighting devices, such as those described above, can be expensive to manufacture and increase an overall weight of the vehicle. Similar issues apply to other non-automotive applications. For example, high power light emitting diode (LED) light engine designs often include metal core printed circuit boards manually mounted (e.g., using a screw or rivet) to large aluminum die-cast (or extruded) heat sinks. Attached to the boards are one or more solid state light sources, such as but not limited to high power LEDs, in which electrical contacts of the LEDs are also used to transfer thermal energy. In addition, many such light engine designs include heat sinks with fins mounted to a heavy, thick conductive plate typically made from extruded or cast aluminum. The conductive plate receives thermal energy from the electrical contacts of the LEDs, and in turn transfers that thermal energy to the fins disposed thereon to cool the LEDs. Besides being heavy, these heat sink configurations require more robust light engine components to ensure mechanical reliability. Thus, the weight of such heat sinks increases the overall weight of the light engine design and, in the context of an automotive application, thereby increases the weight of the vehicle and reduces its fuel efficiency.

One possible solution to reduce the weight of light engines is to use FR4 printed circuit boards that include thermal vias. A thermal via is a metalized hole or bore within the board that promotes the transfer of thermal energy from one side of the board to the other. In addition, each side of the board has copper foil layers that provide very limited transfer of thermal energy due to small thickness of the layers. As a result, thermal energy does not spread throughout the board, but rather remains localized about a heat source (e.g., LEDs) disposed thereon. LEDs are placed on the front side of the board and over the thermal vias. The thermal vias interface with pads of the LEDs that form electrical as well as thermal connections to the board. In such a configuration, the front and back sides of the boards are in thermal as well as electrical communication with one another. On the back side of the board, small, individual heat sinks can be placed opposite the LEDs and over thermal vias. Thus, the heat sinks are also in electrical and thermal communication with the LEDs. In such arrangements, the heat sinks cannot be in contact with each other because such contact will create an electrical short that damages or otherwise causes the LEDs not to emit light. To this end, the heat sinks can be small in size to avoid contact with another, but thus have limited capacity to transfer thermal energy from the LEDs. In addition, the heat sinks proximate the LEDs receive thermal energy, while other heat sinks located away from the LEDs will likely receive little or no thermal energy due to the limited thermal transfer capacity of the thin copper layers between the heat sinks. This is a particular problem for high power LEDs because such LEDs generate large amounts of thermal energy that can degrade or otherwise prevent the function of the LEDs. Thus, there is a need for a light weight light module that effectively transfers thermal energy from high power light sources to effectively cool the light sources.

Embodiments provide a light weight lighting module including a printed circuit board including an insulative core having a first side and a second side, each of the first and second sides of the insulative core including a thermally-conductive layer disposed thereon, and a plurality of thermal vias within the insulative core and in thermal contact with the respective thermally-conductive layers on the first and second sides; a light source attached to the thermally-conductive layer on the first side of the insulative core, the light source in thermal contact with at least one of the thermal vias, the light source further in electrical contact with electrical circuitry that is electrically isolated from the thermally-conductive layers; and a heat sink attached to the thermally-conductive layer on the second side of the insulative core and in thermal contact with the plurality of thermal vias so that the light source transfers thermal energy to the heat sink but remains electrically isolated from the heat sink. In some cases, the heat sink is constructed and arranged as a single unitary piece, and the heat sink having a thermal conductivity of at least 300 W/m-K. In some other cases, the light source is one of a plurality of light sources that are in thermal contact with at least one of the thermal vias, the light sources further in electrical contact with electrical circuitry that is electrically isolated from the thermally-conductive layers. In yet other cases, the light source comprises one or more light emitting diodes (LEDs), the one or more LEDs including a thermal contact and an electrical contact, the thermal contact isolated from the electrical contact and in thermal communication with at least one semiconductor die. In some such cases, the LEDs include a base, the base comprising a non-conductive material that electrically isolates the thermal contact from the electrical contact. In other such cases, the light source can be a single light emitting diode (LED) device. The LED device can include one or more semiconductors dies to generate light. The LED device can also include a housing and a thermal contact and an electrical contact disposed within the housing. In some such cases, the thermal contact can be electrically connected to the electrical contact. For example, the single LED device can be a non-insulative LED device that includes multiple electrical contacts, such as anode and cathode electrical contacts. In addition, one of the electrical contacts can also be a thermal contact that transfers thermal energy to the thermal vias of the printed circuit board to promote the transfer of thermal energy to the heat sink. In some such instances, one of the electrical contacts can be in contact with one or more thermal vias of the printed circuit board. In some other cases, a major surface of the heat sink is soldered directly to the thermally-conductive layer on the second side of the insulative core. In yet other cases, the heat sink includes a plurality of folds so that a flat surface of the heat sink is located opposite at least one of the LEDs. In other cases, the heat sink includes a plurality of fins, the fins having a cross sectional shape of a square, a rectangle, a trapezoid, or a sinusoid. In some cases, the heat sink is a first heat sink, and the module further comprises a second heat sink, a major surface of the second heat sink attached to the thermally-conductive layer on first side of the insulative core. In some such cases, the second heat sink includes an extension member, the extension member attached to one end of the second heat sink and extending to a portion of the printed circuit board that includes the light source. In some other such cases, the first heat sink and the second heat sink comprise copper alloys. In some cases, the light source has a power rating of at least 1 watt. In some other cases, the insulative core comprises a glass-reinforced epoxy laminate material. In yet other cases, the heat sink includes a plurality of fins, the fins extending along the heat sink in a direction along the printed circuit board so as to stiffen the printed circuit board to prevent bending of the printed circuit board along an axis in that direction. In some cases, the printed circuit board includes a thickness in the range of 0.1 mm to 0.75 mm, the thickness including each of the thermally-conductive layers and the insulative core.

Other embodiments provide a lighting device including a housing, a lighting module disposed within the housing, the module comprising a printed circuit board including an insulative core having first side and a second side, each of the first and second sides including a thermally-conductive layer disposed thereon, and a plurality of thermal vias within the insulative core and in thermal contact with the respective thermally-conductive layers on the first and second sides, a plurality of light sources attached to the thermally-conductive layer on first side of the insulative core, each of the light sources in thermal contact with at least one of the thermal vias and further in electrical contact with electrical circuitry that is electrically isolated from the thermally-conductive layers, and a heat sink attached to the thermally-conductive layer on the second side of the insulative core and in thermal contact with the plurality of thermal vias so that the plurality of light sources transfer thermal energy to the heat sink but remain electrically isolated from the heat sink; and an optic disposed within the housing, the optic configured to focus light from the lighting module. In some instances, the optic is one of a light pipe, a reflector, or a lens. In other instances, the heat sink comprises a copper alloy, the heat sink further including an exterior coating on at least one major surface, the exterior coating comprising a tin alloy. In yet other instances, the heat sink is a first heat sink, and the lighting module of the device further comprises a second heat sink, the second heat sink attached to the thermally-conductive layer on the first side of the insulative core. In some instances, the plurality of light sources comprises one of light emitting diodes and laser light sources. In addition, a vehicle can include any of the lighting devices described herein. The light device can be implemented in a vehicle, for instance, as a headlight, taillight, indicator light or access light, name just a few examples.

The features and advantages described herein are not all-inclusive and, in particular, many additional features and advantages will be apparent to one of ordinary skill in the art in view of the drawings, specification, and claims. Moreover, it should be noted that the language used in the specification has been selected principally for readability and instructional purposes and not to limit the scope of the inventive subject matter.

In an embodiment, there is provided a lighting module. The lighting module includes a printed circuit board including an insulative core, wherein the insulative core includes a first side, a second side, and a plurality of thermal vias, wherein each of the first side and the second side of the insulative core include a thermally-conductive layer disposed thereon, and wherein the plurality of thermal vias are within the insulative core and in thermal contact with the respective thermally-conductive layers on the first side and the second side. The lighting module also includes a light source attached to the thermally-conductive layer on the first side of the insulative core, wherein the light source is in thermal contact with at least one of the plurality of thermal vias, and wherein the light source is in electrical contact with electrical circuitry that is electrically isolated from the thermally-conductive layers. The lighting module also includes a heat sink attached to the thermally-conductive layer on the second side of the insulative core and in thermal contact with the plurality of thermal vias so that the light source transfers thermal energy to the heat sink but remains electrically isolated from the heat sink.

In a related embodiment, the heat sink may be constructed and arranged as a single unitary piece, and the heat sink may exhibit a thermal conductivity of at least 300 W/m-K. In another related embodiment, the light source may be one of a plurality of light sources in thermal contact with at least one of the plurality of thermal vias, and the light sources may be in electrical contact with electrical circuitry that is electrically isolated from the thermally-conductive layers.

In still another related embodiment, the light source may include one or more solid state light sources, the one or more solid state light sources including a thermal contact and an electrical contact, wherein the thermal contact may be isolated from the electrical contact and may be in thermal communication with at least one semiconductor die. In a further related embodiment, the one or more solid state light sources may each include a base, the base including a non-conductive material that may electrically isolate the thermal contact from the electrical contact.

In still another related embodiment, the heat sink may include a major surface, and the major surface may be soldered directly to the thermally-conductive layer on the second side of the insulative core. In yet another related embodiment, the heat sink may include a plurality of folds so that a flat surface of the heat sink may be located opposite the light source. In still yet another related embodiment, the heat sink may include a plurality of fins, wherein at least one fin in the plurality of fins may have a cross sectional shape that is a quadrilateral. In yet still another related embodiment, the heat sink may include a plurality of fins, wherein at least one fin in the plurality of fins may have a cross sectional shape comprising at least one edge that is a sinusoid or that includes a curve.

In another related embodiment, the heat sink may be a first heat sink, the lighting module may further include a second heat sink including a major surface, and the major surface of the second heat sink may be attached to the thermally-conductive layer on first side of the insulative core. In a further related embodiment, the second heat sink may include an extension member, and the extension member may be attached to an end of the second heat sink and may extend to a portion of the printed circuit board that includes the light source. In a further related embodiment, the first heat sink and the second heat sink may include copper alloys.

In yet another related embodiment, the insulative core may include a glass-reinforced epoxy laminate material. In still another related embodiment, the heat sink may include a plurality of fins, wherein the fins in the plurality of fins may extend along the heat sink in a direction along the printed circuit board so as to stiffen the printed circuit board to prevent bending of the printed circuit board along an axis in that direction. In yet still another related embodiment, the printed circuit board may include a thickness in the range of 0.1 mm to 0.75 mm, the thickness including each of the thermally-conductive layers and the insulative core.

In another embodiment, there is provided a lighting device. The lighting device includes: a housing and a lighting module disposed within the housing. The lighting module includes
a printed circuit board comprising an insulative core, wherein the insulative core comprises a first side, a second side, and a plurality of thermal vias, wherein each of the first side and the second side of the insulative core comprise a thermally-conductive layer disposed thereon, and wherein the plurality of thermal vias are within the insulative core and in thermal contact with the respective thermally-conductive layers on the first side and the second side;
at least one light sources attached to the thermally-conductive layer on the first side of the insulative core, wherein the at least one light source is in thermal contact with at least one of the plurality of thermal vias and is in electrical contact with electrical circuitry that is electrically isolated from the thermally-conductive layers; and
a heat sink attached to the thermally-conductive layer on the second side of the insulative core and in thermal contact with the plurality of thermal vias so that the at least one light source transfers thermal energy to the heat sink but remains electrically isolated from the heat sink; and an optic disposed within the housing, the optic configured to beam shape light emitted from the lighting module.
   17. The lighting device of claim 16, wherein the heat sink comprises a copper alloy, wherein the heat sink comprises an exterior coating on at least one major surface, and wherein the exterior coating comprises a tin alloy.
   18. The lighting device of claim 16, wherein the heat sink is a first heat sink, and the lighting module further comprises a second heat sink, wherein the second heat sink is attached to the thermally-conductive layer on the first side of the insulative core.
   19. The lighting device of claim 16, wherein the at least one light source comprises a plurality of solid state light sources, wherein the plurality of solid state light sources comprises one of light emitting diodes, laser light sources, and light emitting diodes and laser light sources.

In another embodiment, there is provided a vehicle including the lighting device described above.

### BRIEF DESCRIPTION OF THE DRAWINGS

The foregoing and other objects, features and advantages disclosed herein will be apparent from the following description of particular embodiments disclosed herein, as illustrated in the accompanying drawings in which like reference characters refer to the same parts throughout the different views. The drawings are not necessarily to scale, emphasis instead being placed upon illustrating the principles disclosed herein.

FIG. 1A is a perspective view of a light module configured, according to embodiments disclosed herein.

FIG. 1B is a front view of the light module shown in FIG. 1A.

FIG. 1C is a side view of the light module shown in FIG. 1A.

FIG. 2A is a top view of the printed circuit board of the light module shown in FIG. 1A, according to embodiments disclosed herein.

FIG. 2B is a cross sectional view of a portion of the printed circuit board on which a light source and a heat sink are attached, according to embodiments disclosed herein.

FIG. 2C is an enlarged view of a portion of the printed circuit board on which the light source is attached, according to embodiments disclosed herein.

FIG. 3A is a front perspective view of a light source of the light module shown in FIG. 1A, according to embodiments disclosed herein.

FIG. 3B is a rear perspective view of a light source shown in FIG. 3A.

FIG. 4 is a perspective view of a heat sink of the light module shown in FIG. 1A, according to embodiments disclosed herein.

FIG. 5A is a perspective view of a light module configured according to embodiments disclosed herein.

FIG. 5B is a front view of the light module shown in FIG. 5A.

FIG. 5C is a side view of the light module shown in FIG. 5A.

FIG. 5D is an enlarged view of a portion of the light module shown in FIG. 5A that includes an extension member of the heat sink, according to embodiments disclosed herein.

FIG. 5E is an enlarged view of electrical circuit traces of the printed circuit board shown in FIG. 5A, according to embodiments disclosed herein.

FIG. 6A is a front perspective view of a light source of the light module shown in FIG. 5A, according to embodiments disclosed herein.

FIG. 6B is a rear perspective view of the light source shown in FIG. 6A.

FIG. 7A illustrates a temperature gradient within the light module shown in FIGS. 5A-5E, according to embodiments disclosed herein.

FIG. 7B illustrates a temperature gradient among the light sources of the light module shown in FIG. 7A.

FIG. 8 is a graph illustrating temperature versus time for light modules configured according to embodiments disclosed herein as compared with a previous heat sink design.

FIG. 9 is perspective view of a lighting device that includes a light module configured according to embodiments disclosed herein.

### DETAILED DESCRIPTION

Thus, techniques and architecture are disclosed for are disclosed for a light weight lighting module. In an embodiment, the module includes a printed circuit board (PCB) having a thin, light weight insulative core, such as fiberglass composite board, to receive or otherwise attach components of the module thereto. The core is constructed and arranged to support the components of the light module, for example the light source(s) and optic(s). The core can include mechanical properties so that it does not bend or otherwise deflect under loading that could adversely affect operation of the light module or a lighting device that incorporates the module or both. To this end, the core, in some embodiments, can have a thickness in the range of about 0.100 mm. Note that a core thickness equal to or above 1.5 mm can adversely affect the transfer of thermal energy from the light source to the heat sink.

Disposed on a first side and a second side of the core are conductive layers, such as a copper or aluminum foil layers. The conductive layers promote or otherwise enhance removal of thermal energy from the light source(s) by receiving a portion of the thermal energy therefrom. In particular, the conductive layers can transfer thermal energy to different portions of the heat sink thereby dispersing the heat throughout the heat sink. In some embodiments, the conductive layers are very thin, for example about 0.100 mm thick, and can weigh about 3 ounces (oz) per square foot (ft²). The conductive layers can be made, for example, from materials with a thermal conductivity of at least 300 Watts/meter-Kelvin (W/m-K). Some conductive materials can include copper and aluminum alloys, although other suitable electrically conductive materials can be used.

The PCB further includes a plurality of thermal vias disposed therein. The thermal vias transfer thermal energy from one side of the PCB to the other and through the insulative core of the board. To this end, the vias can be in contact with and pass through the conductive layers so that the vias are exposed on first and second sides of the PCB. In some examples, the thermal vias can be formed by machining holes within the PCB, which in turn are subsequently filled with a conductive material, such as solder. The thermal vias can be located throughout the PCB or at particular locations (e.g., at locations on which the light source(s) is(are) attached), depending on a given application. The thermal vias can also be created within the PCB in random patterns or within particular groups and/or subgroups. Note that thermal vias located directly beneath the light source(s) can effectively transfer thermal energy to the heat sink, and thus such thermal via configurations may be desirable in several applications.

Attached to the first side of the PCB is at least one light source, and in some cases, more than one light source, for example high power solid state light sources, such as but not limited to light emitting diodes or laser light sources, or both. The light source includes a base in which electrical and thermal contacts are disposed therein. The base can be made from electrically insulative and thermally conductive materials, such as ceramic materials and other electrically insulative and thermally conductive materials, that electrically isolates the electrical contacts from the thermal contacts and thermally couples the light generating component (e.g., semiconductor die) to the thermal contact. Materials, such as aluminum nitride (AlN) ceramics and aluminum oxide (Al₂O₃) and silicon dioxide (SiO₂) can be suitable base materials, although any number of electrically insulating and thermally conductive materials can be used. This electrical isolation between the thermal and electrical contacts is particularly noteworthy because with the thermal contacts that heat sink can now be in thermal communication with multiple light sources without damaging the light sources by causing an electrical short. In other embodiments, the light sources can be electrically isolated from the thermal pads based on an internal electrical circuit configuration that allows the thermally-conductive plane to be decoupled from the electrical circuitry. In addition, the light sources can include one or thermal contacts (e.g., thermal pads) to transfer heat to the thermal vias and conductive layers. The thermal contacts, in some embodiments, can be located behind a semiconductor die of the light source in an effort to promote a maximum amount of heat transfer from the die to the thermal contact.

In some embodiments, the PCB also includes a heat sink attached to the second side of the PCB and made from high thermal conductivity materials. The heat sink, in some such embodiments, is made from materials having a thermal conductivity of at least 300 W/m-K, such as copper alloys. In addition, the heat sink, in some embodiments, is constructed and arranged as a single unitary piece using, for example stamping, folding, or welding processes (or a combination thereof). The heat sink can be manufactured from relatively thick materials as compared with the conductive layers of the PCB. To this end, the heat sink can include, for instance, a thickness of about 0.5 mm, in some embodiments. Note that the high thermal conductivity and relative thickness of the heat sink allows the thermal energy received by the heat sink to spread throughout a greater portion of the heat sink (e.g., to the portions of the heat sink remotely located from the light source) to reduce localized heating at the light source. In addition, the heat sink can include an outer coating, such as tinned outer coating, so that the heat sink can be attached directly to the printed circuit board using, for example, pick-and-place and reflow soldering processes.

Once assembled together, the light source(s) and the heat sink are in contact with the plurality of thermal vias of the PCB so that thermal energy from the light source(s) can be transferred to the heat sink directly using the vias located under (or otherwise adjacent to) the light source(s) and indirectly through the copper foil layers and thermal vias located remotely from the light source(s). This transfer of thermal energy from the light source(s) to the heat sink lowers the temperature of light source(s) to prevent their degradation due to localized heating effects. In addition, thermal conductivity characteristics of the heat sink allow for a more even distribution of thermal energy across the heat sink (e.g., heat can be spread to perimeter surfaces of the heat sink near edges of the PCB) to more effectively cool the light source(s).

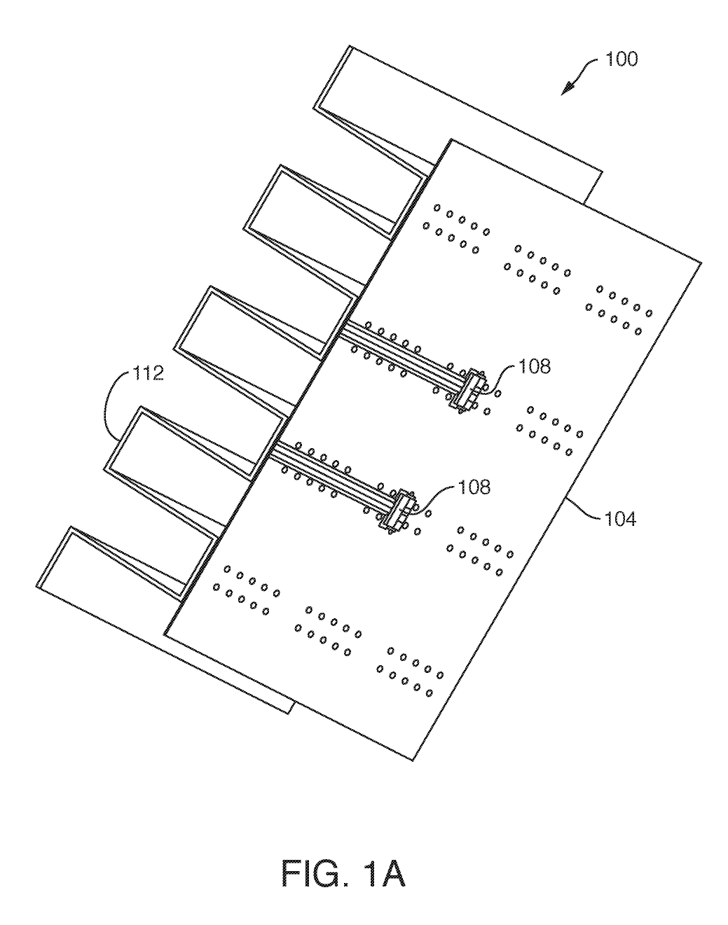

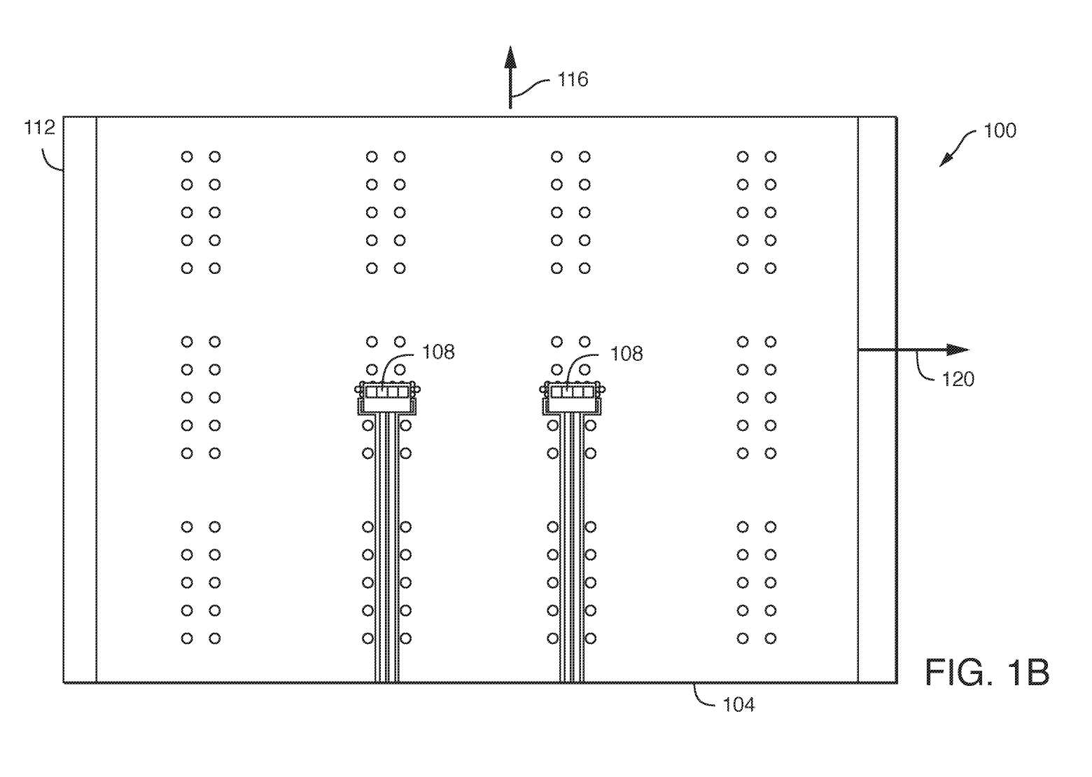

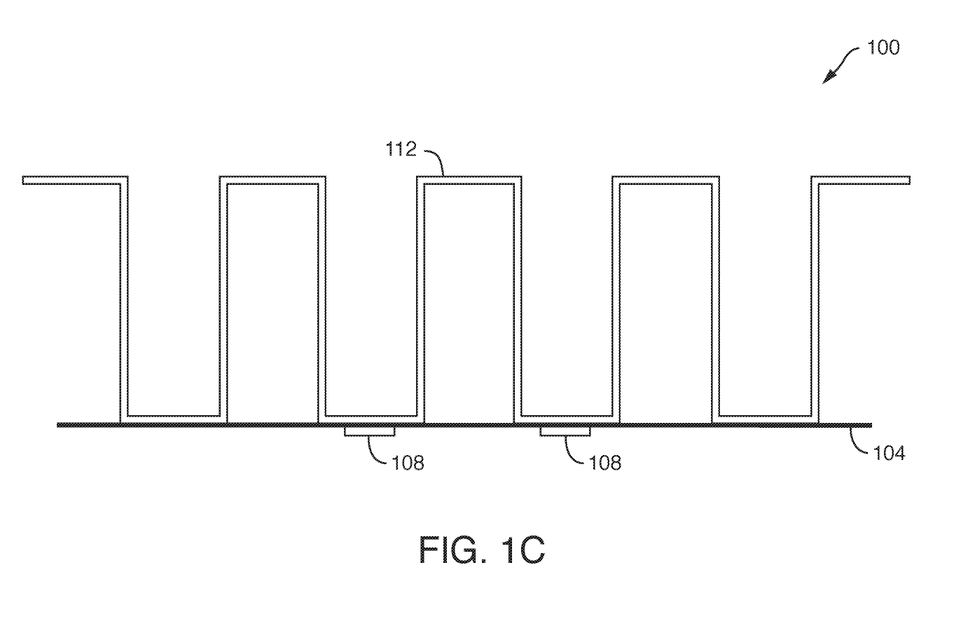

FIG. 1A is a perspective view of a light module 100. FIGS. 1B-1C are a front view and a side view of the light module 100 shown in FIG. 1A, respectively. In some embodiments, the light module 100 is a light weight lighting module for one or more high power light sources (e.g., a power rating of at least 1 watt). In particular, the light module is constructed and arranged so that the light source is electrically isolated from a heat sink disposed on the module. As such, the heat sink can now be in thermal contact with multiple light sources instead of just a single light source, though some embodiments include just a single light source. The heat sink configurations can be, for example, of a unitary piece design so that thermal energy from, for example, multiple, high power light sources can distributed across the heat sink. Such configurations more effectively prevent overheating of the light sources that can degrade or otherwise inhibit function of the light source by enabling more thermal energy to spread throughout more portions of the heat sink. This is particularly useful in closed environments, such as within a headlight or taillight assembly, in which air flow used to cool the module is restricted. As can be seen with reference to FIG. 1A, the light module 100 can include a circuit card, electrical substrate, or printed circuit board (PCB) 104 (hereinafter simply referred to as a printed circuit board (PCB) 104). Attached to the PCB 104 is one or more light sources 108 and a heat sink 112.

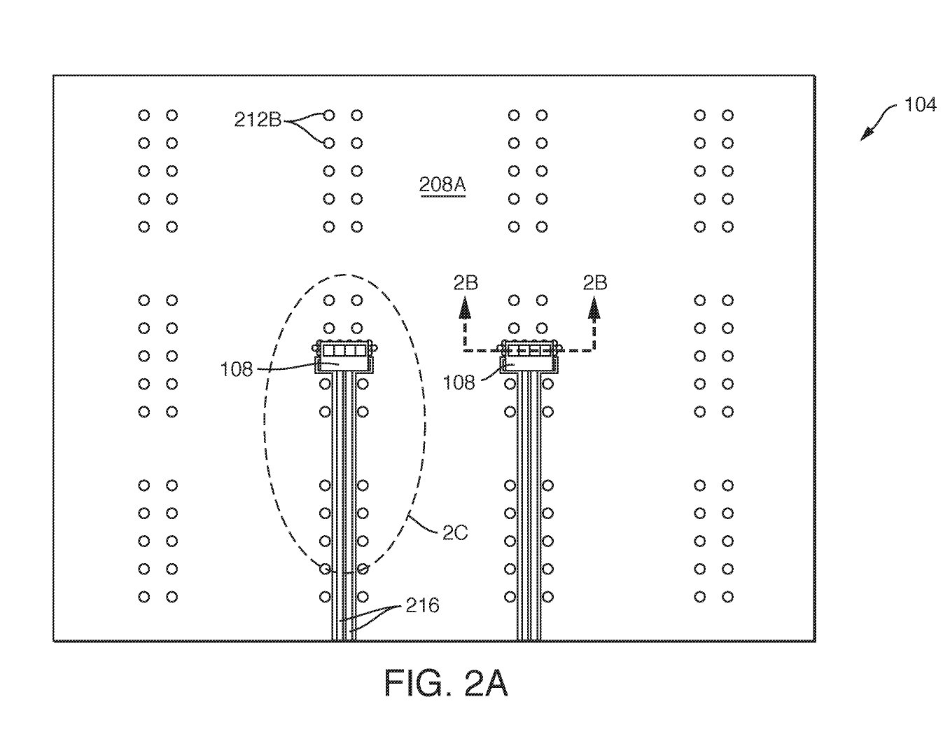

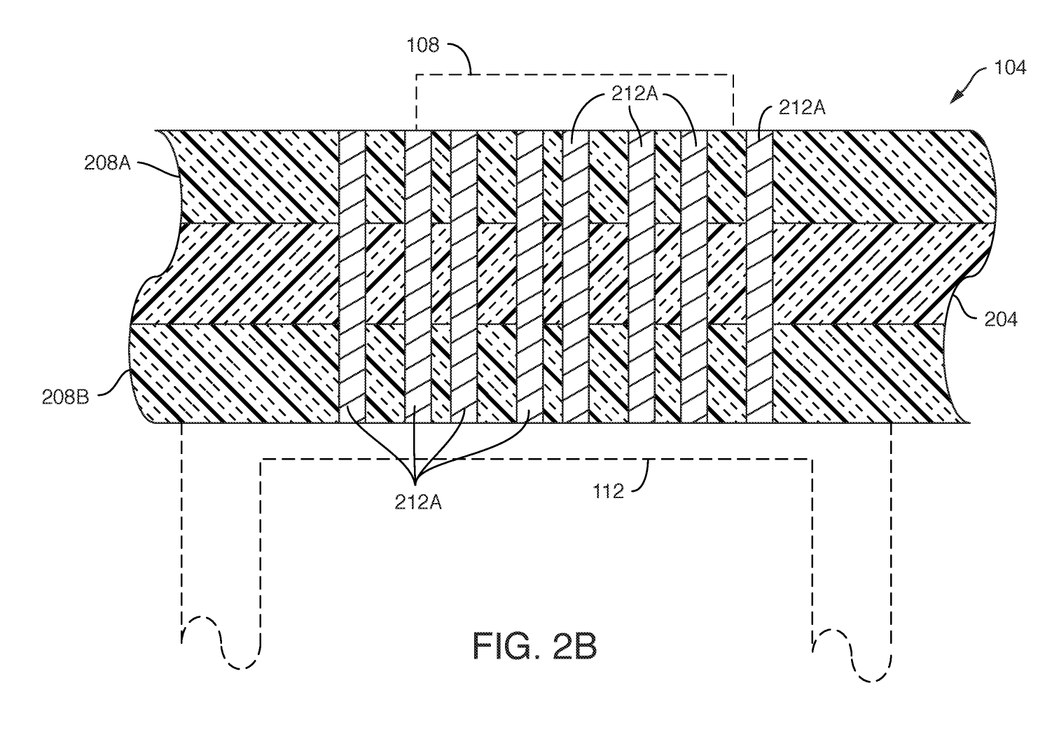

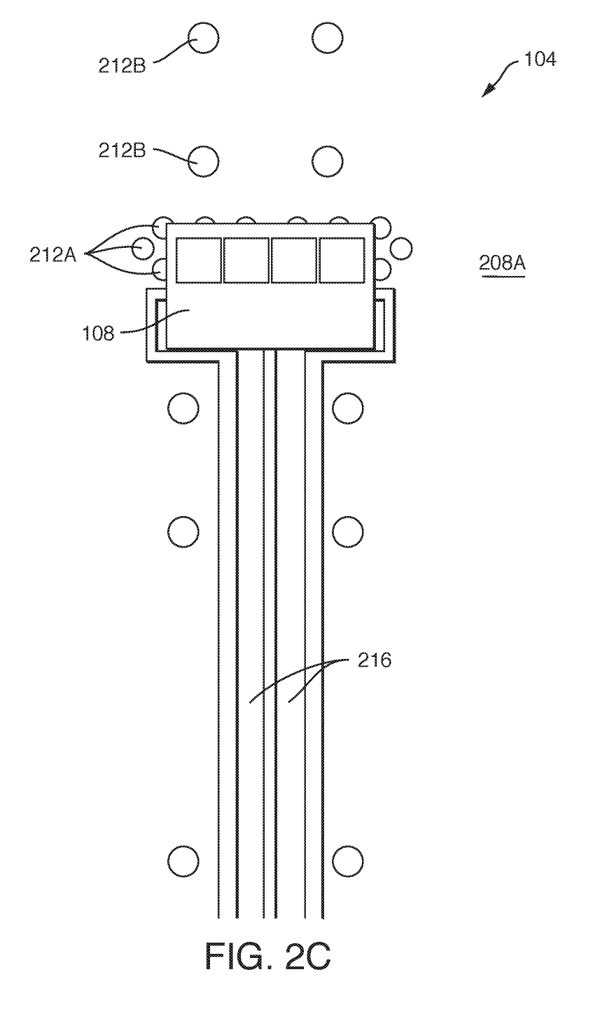

As can be further seen in FIG. 1C, the one or more light sources 108 are attached to one side of the PCB 104 while the heat sink 112 is attached to the opposing side. Both the one or more light sources 108 and heat sink 112 are affixed onto the PCB 104 so that the one or more light sources 108 are in thermal communication with the heat sink 112 using thermal vias, as will be described further herein. It is particularly noteworthy that the heat sink 112 can be attached to the PCB 104 without the use of thermal interface materials, such greases or thermal pads, that increase the cost to manufacture (and disposal of) the light modules. Instead, the heat sink 112 is attached directly to the surface of the PCB 104. In addition, in some embodiments, a flat surface of the heat sink 112 is in contact with a portion of the PCB 104 located directly under one of the one or more light source 108 (as further shown in FIG. 2C) to promote heat transfer between the components. To this end, the portion of the heat sink 112 in contact with a back conductive layer 208B is in the range, for example, of 10 to 30 percent of the surface area of one side of the heat sink 112, according to some such embodiments. Such configurations may be desirable in some instances because thermal energy passes directly from one component to the other using the thermal vias instead of passing indirectly through the layers (e.g., copper foil layers) of the PCB 104. In addition, the configuration as shown in FIGS. 1A-1C can be particularly useful in automotive applications, such as in low beam or high beam lamps, in which an optic, such as a large reflector or lens, is mounted to a front side of the light module 100. The large sized optic, however, provides little space to mount a heat sink on the frontside of the PCB 104. Thus, in many such embodiments, the lighting device includes a single heat sink on the backside of the PCB 104.

FIG. 2A is a top view of the printed circuit board (PCB) 104 of the light module 100 shown in FIG. 1A. FIG. 2B is a cross sectional view of a portion of the printed circuit board 104 on which a light source 108 and a heat sink 112 are attached. FIG. 2C is an enlarged view of a portion of the printed circuit board 104 on which the light source 108 of FIG. 2B is attached. In these embodiments, the printed circuit board 104 is configured to mechanically support components of the light module 100, such as the light source 108 and the heat sink 112. The PCB 104 may also include mounting locations on which to attach the light module 100 to a housing of a light assembly, as will be described further herein. The PCB 104 may also provide electrical connections to operate the one or more light sources 108, such as but not limited to solid state light sources. Generally speaking, the PCB 104, in some embodiments, is a thin, light weight circuit card, electrical substrate, or printed circuit board. Here, the PCB 104 is a light weight printed circuit board that includes a core 204, conductive layers 208A and 208B (collectively conductive layers 208), a plurality of thermal vias 212A and 212B (collectively a plurality of thermal vias 212), and electrical traces 216. Together, the core 204 and the conductive layers 208 form a multi-layer PCB. In some embodiments, the core 204 is an inner portion of the multi-layer PCB covered by outer layers, for example the conductive layers 208. In some embodiments, the core 204 is a single core, and in some embodiments, a multi-layer core. The core 204, in some embodiments, is a composite board made from materials, such as a combination of fibers and resins. In some embodiments, the core 204 is manufactured using glass-reinforced epoxy laminate materials, for example woven fiberglass cloth disposed within an epoxy resin binder. The core 204, in some embodiments, also includes additional layers of material, such as inner conductive layers, so as to form a multi-layer core. In addition, the core 204 has a thickness, for example, of at least 0.127 millimeters (mm) so as to provide enough stiffness to resist bending of the PCB 104, in some embodiments. The core 204 in some embodiments includes a thickness in the range of 0.01 mm to 3.0 mm, depending on a given application.

Disposed on each side of the core 204 are the conductive layers 208, such as copper foil layers. In general, the conductive layers 208 are configured to transfer thermal energy from the one or more light sources 108 to other components attached to the PCB 104, such as the heat sink 112. The conductive layers 208, in some embodiments, are manufactured from materials with high thermal conductivity, such as copper or alloys thereof. In addition, the conductive layers 208, in some embodiments, include a uniform thickness to provide a consistent or otherwise known rate of transfer of thermal energy. In particular, the conductive layers 208 in some embodiments include a thickness in the range of at least 0.100 mm to 0.125 mm and a thermal conductivity in the range of at least 300 W/m-K. In some embodiments, the conductive layers 208 are copper foil layers having a weight of approximately 3 oz/ft². The conductive layers 208 described above provide sufficient thermal conductivity without significantly increasing the cost to manufacture the light module 100. In other embodiments, the conductive layers 208 have a thickness of approximately 0.105 mm and an associate thermal conductivity between 350 and 450 W/m-K. To this end, the combined thickness of the PCB 104, in some embodiments, is in the range of at least 0.3 millimeter (mm) to about 1.0 mm. In other embodiments, the PCB 104 has a thickness in the range of 0.1 mm to about 0.75 mm. Such thickness ranges allow for effective thermal energy transfer through the PCB 104 to the heat sink 112 without diminishing the structural integrity or manufacturability of the PCB 104. The PCB 104, in some embodiments, includes a thickness in the range of 0.01 mm to 3.0 mm, depending on the particular application.

The PCB 104 further includes the plurality of thermal vias 212 configured to transfer thermal energy from the one or more light sources 108 to the heat sink 112. The plurality of thermal vias 212, in some embodiments, are pathways or vertical interconnect accesses that form a thermal connection between components disposed on opposite sides of the core 204. The plurality of thermal vias 212 are formed, for example, in some embodiments, by machining a hole within the PCB 104 and filling that hole with a conductive material, such as solder, using, for example but not limited to, soldering techniques. Note that the plurality of thermal vias 212, in some embodiments, pass through the core 204 and each of the conductive layers 208 so that the plurality of thermal vias 212 are exposed on outer surfaces of the PCB 104. The plurality of thermal vias 212, in some embodiments, pass through the core 204 and just one (or neither) of the conductive layers 208.

The plurality of thermal vias 212 are arranged in a pattern in some embodiments, such as but not limited to an array, so as to enhance or otherwise promote thermal energy transfer from the one or more light sources 108 to the heat sink 112. For instance, the plurality of thermal vias 212 as shown, are arranged within the PCB 104 in groups and/or subgroups that form a grid-like pattern. In some embodiments, the plurality of thermal vias 212 are located within the PCB 104 so that the one or more light sources 108 partially or totally cover at least some of the plurality of thermal vias 212 of the PCB 104. For instance, as can be seen in FIG. 2A, the plurality of thermal vias 212A are arranged in a subgroup within the PCB 104 so that the one or more light sources 108 cover at least some of the thermal vias 212A. In some embodiments, the PCB 104 also includes the thermal vias 212B, which may increase the transfer of thermal energy from the one or more light sources 108 to the heat sink 112. In particular, not all of the thermal energy generated by the one or more light sources 108 is transferred to the heat sink 112 using the thermal vias 212A. Rather, some of that thermal energy is transferred through the conductive layer 208A located on the front side of the PCB 104 to other portions of the PCB 104 to further cool the one or more light sources 108. The thermal vias 212B in those other portions of the PCB 104 receive the thermal energy from the conductive layer 208A on the front side of the PCB 104 and transfer that energy to the heat sink 112 on the back side of the PCB 104. In some embodiments, the PCB 104 includes the thermal vias 212A and not the thermal vias 212B. Such configurations may be appropriate when the light module 100 includes an additional heat sink disposed on the front surface of the printed circuit board 104, such as light module 500 described in greater detail below.

In some embodiments, the plurality of thermal vias 212 have differing sizes and/or spacing therebetween. For example, as shown in FIG. 2C, the thermal vias 212A and the thermal vias 212B include diameters of varying sizes and are differently spaced from one another. In some embodiments, the thermal vias 212A include a diameter that is smaller than the diameter of the thermal vias 212B. The smaller diameter of the thermal vias 212A allows the thermal vias 212A to be positioned closer to one another so that as many of the thermal vias 212A as possible are located beneath the one or more light sources 108 without adversely affecting the structural integrity of the PCB 104. In some embodiments, the thermal vias 212A include a diameter of approximately 0.3 mm. The diameter of the thermal vias 212A, in some embodiments, is in the range of 0.1 to 0.50 mm, depending on the particular use case. In some embodiments, the thermal vias 212B include a diameter larger than that of the thermal vias 212A because the thermal vias 212B are spaced further apart from one another without adversely affecting the thermal conductively and/or structural integrity of the PCB 104. For example, in some embodiments the thermal vias 212B include a diameter of approximately 0.76 mm. In some embodiments, the diameter of the thermal vias 212B is in the range of 0.60 to 1.00 mm, depending on the application.

In some embodiments, the distance between the plurality of thermal vias 212 varies based on their locations within the PCB 104. In some embodiments, locations within the PCB 104 at which the one or more light sources 108 are affixed experience large amounts of localized heating due to the operation of the one or more light sources 108. To effectively and efficiently transfer this thermal energy, the thermal vias 212A in the plurality of thermal vias 212 located beneath or directly adjacent to the one or more light sources 108 are positioned as close to another as possible. By densely locating the thermal vias 212A beneath the one or more light sources 108, more thermal energy can be transferred from the one or more light sources 108, because the thermal vias 212A are more efficient conductors of thermal energy than the conductive layers 208. To this end, the thermal vias 212A in the plurality of thermal vias 212, in some embodiments, are positioned at a distance of 0.5 mm from one another. In some embodiments, the distance between the thermal vias 212A is in the range of 0.2 mm to 1.0 mm. In some embodiments, the thermal vias 212B in the plurality of thermal vias 212 are less densely packed together or otherwise positioned relative to one another, because the thermal vias 212B receive less thermal energy from the one or more light sources 108. For example, in some embodiments, the thermal vias 212B are separated by a distance of 1.8 mm. The distance between the thermal vias 212B, in some embodiments, is in the range of 0.5 mm to 2.5 mm.

The PCB 104 also includes electrical traces 216 that form a path to transfer electricity from a source of electrical power to the one or more light sources 108. In general, the electrical traces 216 are constructed and arranged so that they occupy a relatively small area within the PCB 104, so as to not interfere with large portions of the conductive layers 208 that are used for thermal energy transfer. The electrical traces 216 are electrically isolated from one another as well as from the conductive layers 208 to prevent an electrical short of the circuit. As can be seen, in some embodiments, the electrical traces are a flat, narrow portion of the conductive layer 208A made using techniques such as but not limited to etching. The electrical traces 216 vary in size depending on needs of operating the one or more light sources 108. In some embodiments, the electrical traces 216 interface with or otherwise are in contact with electricals pads of the one or more light sources 108, as described further herein. Note that the PCB 104 as variously descried herein, in some embodiments, is manufactured using 3-D printing technology, as will be appreciated.

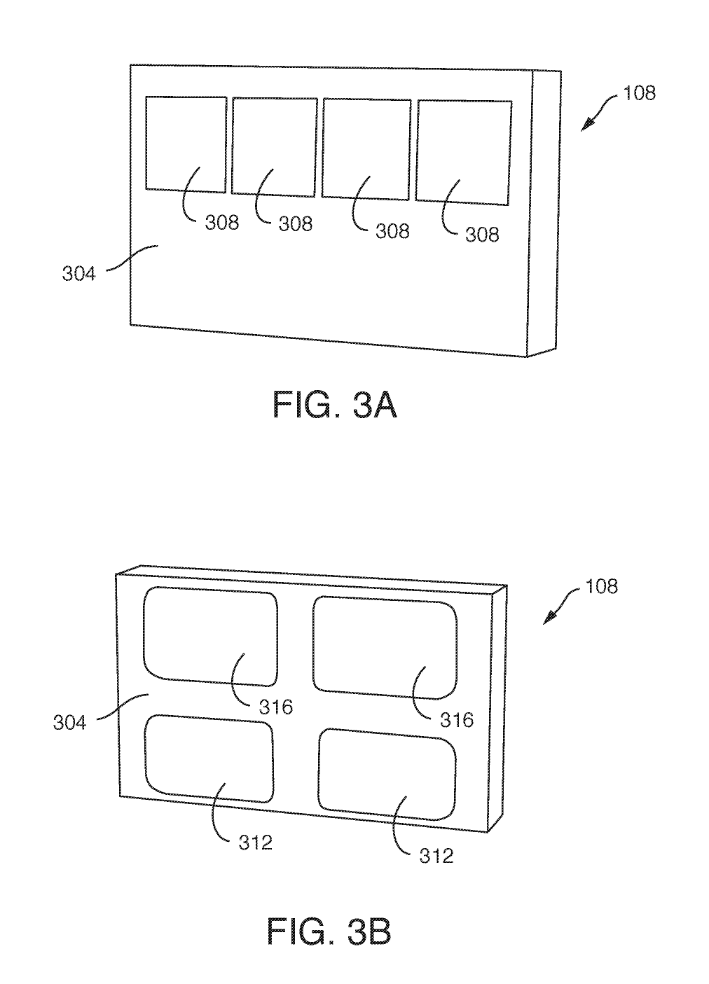

FIGS. 3A-3B are a front perspective view and a rear perspective view of the one or more light sources 108 of the light module 100 shown in FIG. 1A. The one or more light sources 108 are attached to the PCB 104 and configured to generate light. In some embodiments, the one or more light sources 108 are one or more solid state light sources, such as but not limited to LEDs, OLEDs, PLEDs, laser diodes, or the like, and in some embodiments, these are high power, having a power in the range of 1 Watt (W) to about 6 W, depending on the application. The one or more light sources 108 can also be laser light sources having a power rating of at least 1 W, depending on the particular use case. The one or more light sources 108, in some applications, include a power rating in the range of 0.25 W to 25 W or more. In some embodiments, the one or more light source 108 are attached or otherwise affixed to the electrical traces of the PCB 104, for example using reflow soldering processes. In FIGS. 3A-3B, the one or more light sources 108 include a base 304, semiconductor dies 308, a plurality of electrical contacts 312, and thermal contacts 316.

The base 304 is configured to house light source components and enable attachment of the one or more light sources 108 to the PCB 104. In some embodiments, the base 304 is configured to electrically isolate the thermal contacts 316 from the plurality of electrical contacts 312, so that the heat sink 112 can be in thermal contact with multiple ones of the one or more light sources 108. The base 304 also facilitates thermal energy transfer from the semiconductor dies 308 to the thermal contacts 316 to lower light source temperature. In some embodiments, the base 304 is made from electrically insulative and thermally conductive materials, such as but not limited to ceramics or polymeric materials. In some embodiments, the base 304 is manufactured from materials, such as aluminum nitride (AlN) ceramics and aluminum oxide (Al₂O₃), just to name a few. As can be seen in FIG. 3B, the base 304 in some embodiments surrounds each of the plurality of electrical contacts 312 and the thermal contacts 316, so that the plurality of electrical contacts 312 and the thermal contract 316 are not in electrical communication or otherwise electrically coupled to one another. In some embodiments, the base 304 thermally couples the light emitting components (e.g., the semiconductor dies 308) to the thermal contacts 316, so as to transfer thermal energy from the one or more light sources 108.

On one side of the base 304 are the semiconductor dies 308, or chips (hereinafter referred to as the semiconductor dies 308) that are configured to generate light. The semiconductor dies 308 are, in some embodiments, electrically connected or coupled to the plurality of electrical contacts 312 located on the opposite side of the base 304, as described further herein. Within the base 304 there can be one or multiple semiconductor dies 308, depending on the application. As shown in FIG. 3A, the base 304 includes four semiconductor dies 308, but embodiments need not be so limited. In some embodiments, the base 304 includes one, two, three, or more than five semiconductor dies 308, depending on a given use case. The semiconductor dies 308 are, in some embodiments, arranged side-by-side with one another, as shown in FIG. 3A. In some embodiments, the semiconductor dies 308 are located above or below one another. In some embodiments, the arrangement of the semiconductor dies 308 is in a uniform pattern, and in some embodiments, in a non-uniform pattern, as the case may be. Other die configurations will be apparent in light of the present disclosure.

On the other side of the base 304 is the plurality of electrical contacts 312 that electrically connect the one or more light sources 108 to a source of power, such as a power circuit of a vehicle. The plurality of electrical contacts 312 are also connected to the semiconductor dies 308 to supply the semiconductor dies 308 with electrical power to generate light. To this end, one of the plurality of electrical contacts 312 can be a positively charged electrode (e.g., an anode (+)) in which current flows into from a semiconductor die 308. On the other hand, another of the plurality of electrical contacts 312 can be a negatively charged electrode (e.g., a cathode (−)) in which current flows from and is received at the semiconductor die 308. In some embodiments, the plurality of electrical contacts 312 are configured to contact the electrical traces 216 of the PCB 104 to form an electrical connection therebetween. To this end, the plurality of electrical contacts 312, in some embodiments, are pads that contact or otherwise receive the electrical traces 216. In some embodiments, at least some of the plurality of electrical contacts 312 are pads that include a quadrilateral cross sectional shape. The cross sectional shape of at least some of the plurality of electrical contacts 312, in some embodiments, is a square, a circle, an oval, a polygon, or any other shape, whether uniform or not, just to name a few.

The base 304 includes thermal contacts 316 that receive thermal energy from the semiconductor dies 308 and transmit that energy from the one or more light sources 108 to the PCB 104. In some embodiments, the thermal contacts 316 are in the form of a thermal pad configured to contact a surface of the PCB 104. As can be seen, in FIG. 3B, the base 304 includes two thermal contacts 316, but this may not be the case in all embodiments. In some embodiments, the base includes just one thermal contact 316, and in some embodiments, several thermal contacts 316 (e.g., three or four pads), depending on a given application. In some embodiments, the thermal contacts 316 are located behind or otherwise adjacent to the semiconductor dies 308 so as to promote thermal energy transfer from the semiconductor dies 308 to the thermal contacts 316. In some embodiments, the thermal contacts 316 are made from conductive materials including copper or aluminum, for example.

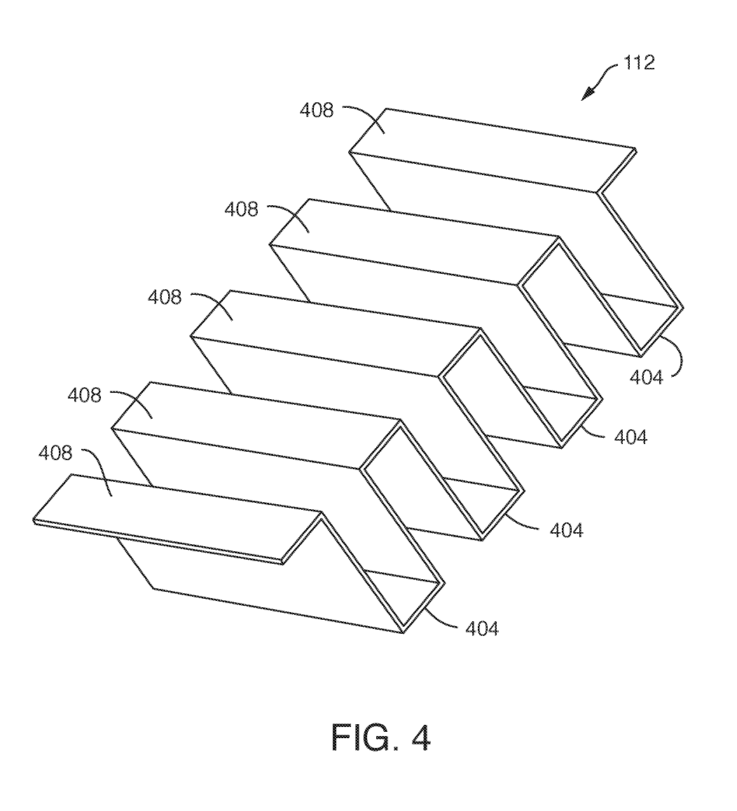

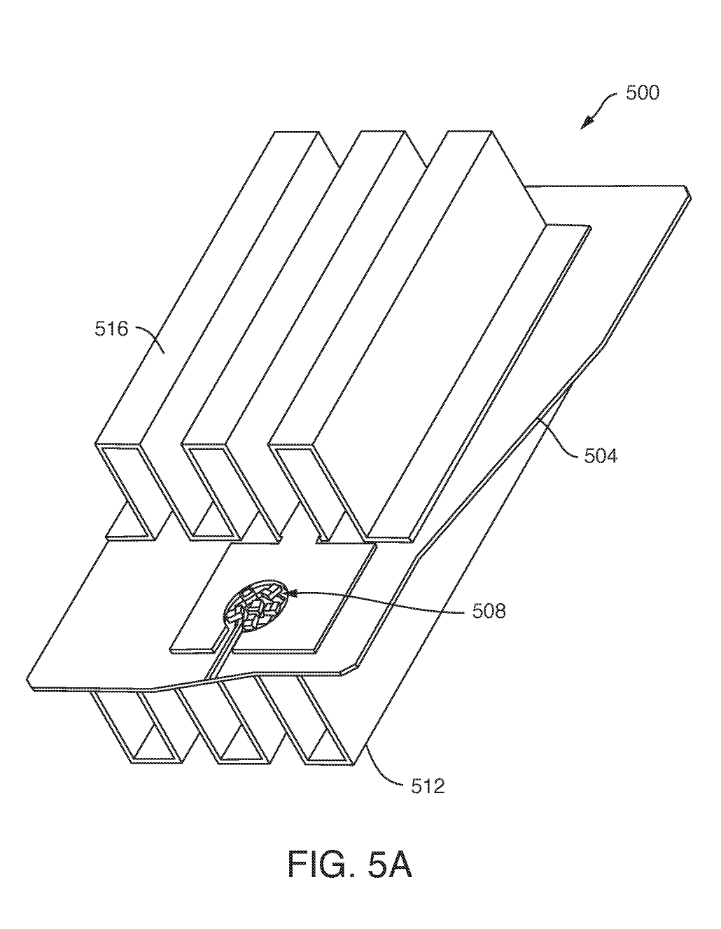

FIG. 4 is a perspective view of the heat sink 112 of the light module 100 shown in FIG. 1A. To dissipate thermal energy generated by the one or more light sources 108, the light module 100 includes the heat sink 112 affixed to the PCB 104. In some embodiments, surfaces of the heat sink 112 (e.g., surfaces 404) are affixed to the PCB 104 using techniques, such as reflow solder processing, so that the heat sink 112 is directly attached to the PCB 104. The heat sink 112 is configured to transfer thermal energy from the one or more light sources 108 to the surrounding environment to cool and prevent degradation of the one or more light sources 108. As previously described herein, in some embodiments the heat sink 112 is attached to the PCB 104 such that a portion of the heat sink 112 (e.g., surfaces 404) is in contact with the PCB 104 at a location directly under or otherwise opposite the one or more light sources 108 to enhance heat transfer characteristics of the light module 100. In some embodiments, the heat sink 112 is a single unitary piece made by, for example, using stamping, folding, or other metal forming techniques, but this need not be the case in all instances. For instance, in some embodiments, the heat sink 112 is a unitary piece made from several smaller pieces joined together, for example using welding processes.

The heat sink 112, in some embodiments, is constructed and arranged to promote thermal energy transfer from the one or more light sources 108 to the surrounding environment. For example, in some embodiments, the heat sink 112 is made of materials having a thermal conductivity of approximately about 400 W/m-K. In some embodiments, the heat sink 112 is made from materials with a thermal conductivity in the range of 250 to 500 W/m-K. Examples of heat sink materials include copper and alloys thereof, just to name a few. Such materials can be used in the form of metal sheets so that the heat sink 112 can be a sheet-metal heat sink. In some embodiments, the heat sink 112 has a thickness of approximately 0.5 mm. In some embodiments, the heat sink 112 has a thickness in the range of 0.2 to 1.0 mm. Note that heat sink thickness varies, in some embodiments, based on the power rating of the one or more light sources 108 and a given size of the heat sink 112. Sheet-metal heat sink configurations are lighter than cast or extruded heat sinks of previous designs, and thus provide a savings in weight of the light module 100, that can be particularly useful and desirable in many applications, such as automotive applications.

In some embodiments, the heat sink 112 provides structural support to the PCB 104 to further stiffen or otherwise make rigid the light module 100. This is particularly noteworthy in automotive applications, in which components experience significant vibrations that may move the PCB 104, which could cause it to crack and the light module 100 to fail. The heat sink 112 prevents such damage by providing a rigid structure on which to mount the PCB 104. In more detail, in some embodiments the heat sink 112 includes several folds or bends that form box or fin-like structures 408 (hereinafter referred to as fins 408) that extend in a direction along a transverse axis 116 of the PCB 104 (shown in FIG. 1B) that opposes bending or other movement of the PCB 104 about the transverse axis 116. In some embodiments, the fins 408 extend parallel to or otherwise along a longitudinal axis 120 of the PCB 104 (also shown in FIG. 1B) to oppose bending of the PCB 104 along the longitudinal axis 120. To this end, the heat sink 112, in some embodiments, includes a cross sectional shape that looks like a square wave or step function, as shown in FIG. 4. The cross sectional shape of the heat sink 112, in some embodiments, is rounded, curved, includes a curve, quadrilateral, rectangular, or trapezoidal, to name just a few variations. In some embodiments, the shape of the heat sink 112 is uniform (e.g., as shown in FIG. 4) or non-uniform (e.g., with fins 408 of varying heights and widths), depending on a particular use case. No matter its configuration, the heat sink 112 is, in some embodiments, directly attached to the PCB 104. To this end, the portion of the heat sink 112 that attaches to the PCB 104 (e.g., major surfaces 404) can provide sufficient surface area so that the joint therebetween can withstand tensile loads caused by the weight of the heat sink 112. In some embodiments, the heat sink 112 has a length that is substantially the same as a length of the PCB 104 to provide further support of the PCB 104, but this need not be the case in all instances.

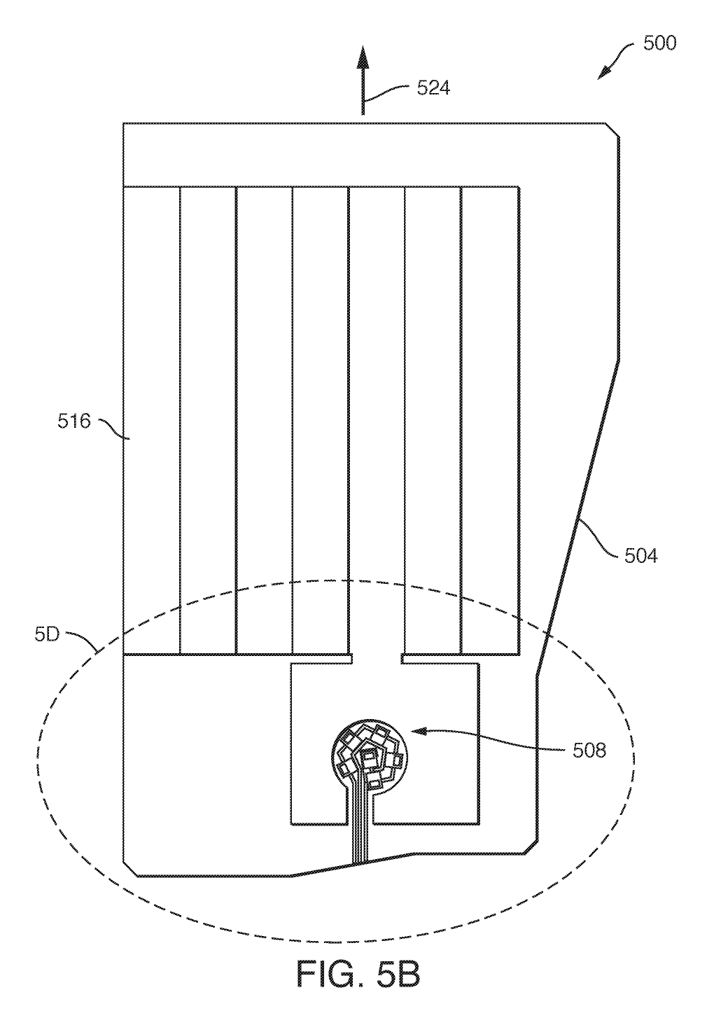

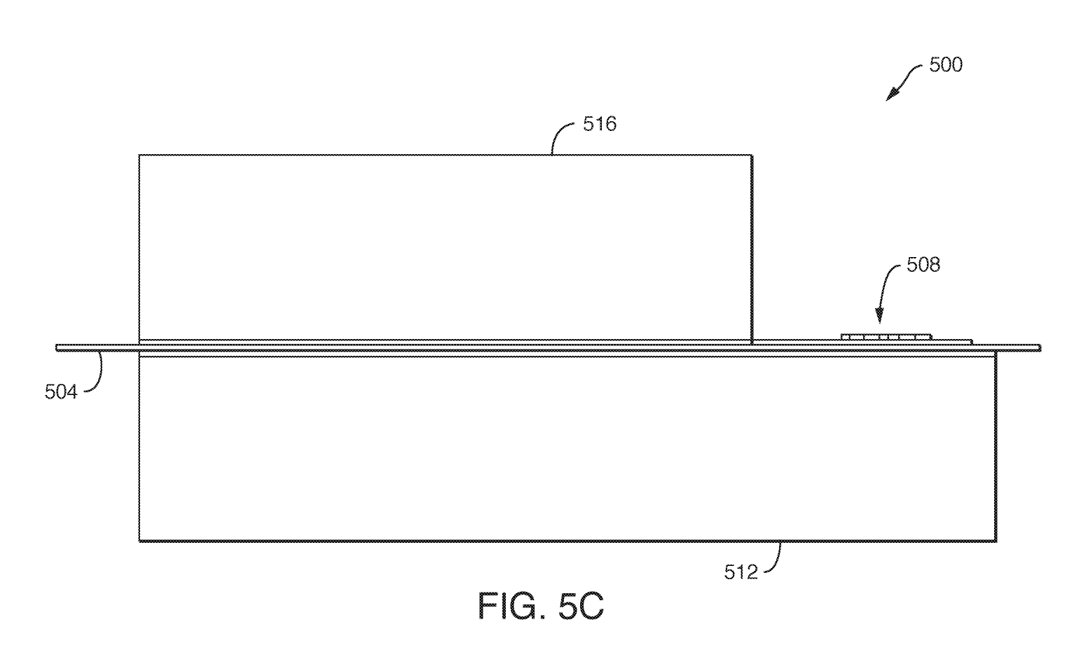

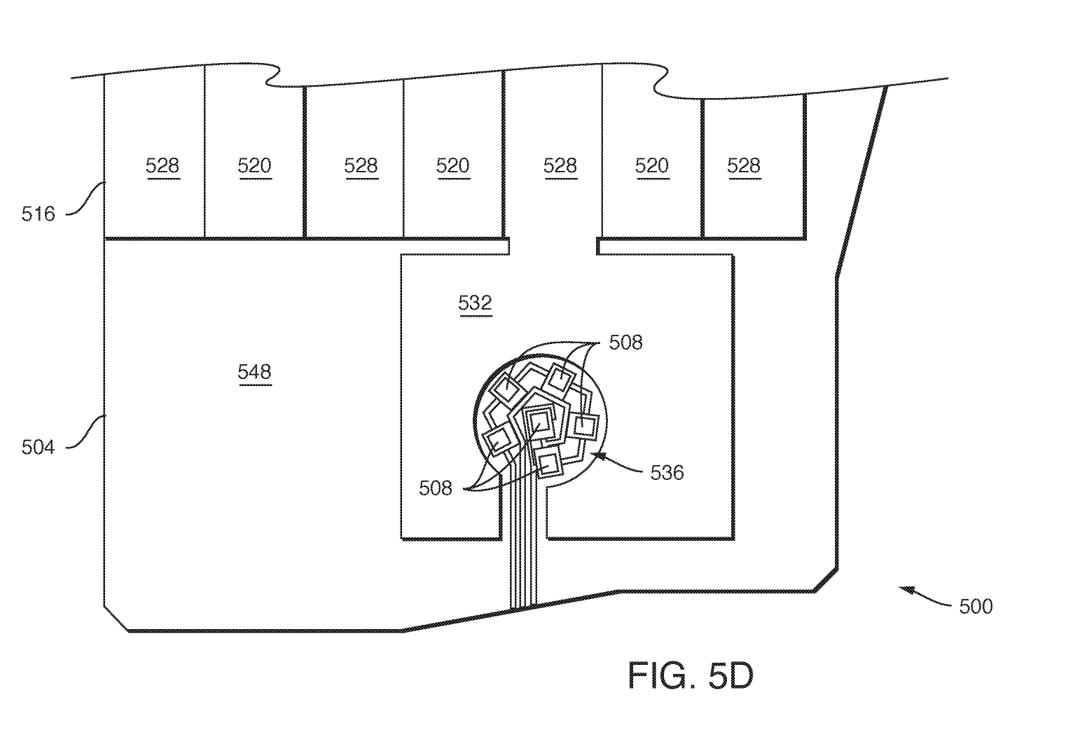

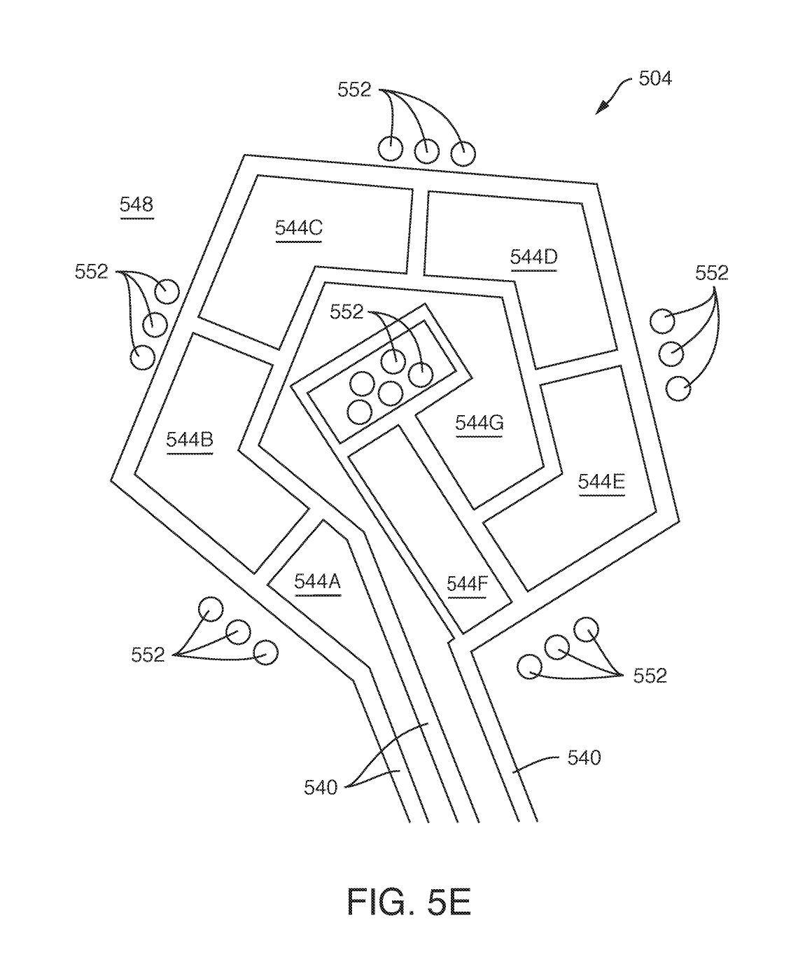

FIG. 5A is a perspective view of a light module 500. FIG. 5B is a front view of the light module 500 shown in FIG. 5A. FIG. 5C is a side view of the light module 500 shown in FIG. 5A. FIG. 5D is an enlarged view of a portion of the light module 500 shown in FIG. 5A that includes an extension member 532 of a heat sink 516. FIG. 5E is an enlarged view of electrical traces 544 of a printed circuit board 504 shown in FIG. 5A. In some embodiments, the optic or lens used with the light module 500 is small enough so that an additional heat sink can be affixed to a front surface of a printed circuit board. The additional heat sink allows for the transfer of more thermal energy from the light sources.

In some embodiments, the light module 500 includes a printed circuit board (PCB) 504, one or more light sources 508, a rear heat sink 512, and a front heat sink 516. The PCB 504, the one or more light sources 508, and the rear heat sink 512 are similar to those previously described herein in relation to FIGS. 1A-4.

As can be seen, the front heat sink 516 provides additional capacity to transfer thermal energy from the one or more light sources 508. Significantly, the front (or component side) heat sink 516, in some embodiments, is affixed to the PCB 504 so that it does not contact the one or more light sources 508 disposed on the PCB 504. Such contact would cause an electrical short and damage to the one or more light sources 508. Moreover, in some embodiments, the front heat sink 516 are configured to provide ample space along a front surface of the PCB 504 to enable coupling of an optic (e.g., a reflector) to the PCB 504 and over the one or more light sources 508.

The front heat sink 516, in some embodiments, is configured differently from the rear heat sink 512 to accommodate installation of the optic about the one or more light sources 508. In particular, unlike the fins and contact surfaces of the rear heat sink 512 that may extend along a length of the PCB 504, here, box-like members or fin structures 520 (hereinafter referred to as fins 520) of the front heat sink 516 extend along just a portion of a front side of the PCB 504. Such heat sink configurations allow for the installation of the optic onto the front side of the PCB 504 and over the one or more light sources 508. The fins 520, in some embodiments, can extend along 10 percent, 20 percent, 35 percent, 50 percent, or 75 percent of a length of the PCB 504 and in a direction along a longitudinal axis 524. Similarly, the contact segments or portions 528 of the front heat sink 516, in some embodiments, extend along the front surface of the PCB 504 in the same fashion as the fins 520, described above. The contact portions 528, however, in some embodiments, are longer or shorter than the fins 520, depending on a given application. In some embodiments, the contact portions 528 are different relative to one another (e.g., of varying lengths or widths).

The front heat sink 516, in some embodiments, includes an extension member 532 to enhance or otherwise improve thermal energy transfer from the one or more light sources 508 to the front heat sink 516. As seen in FIG. 5D, the extension member 532, in some embodiments, is a flat sheet that extends along the PCB 504 and as close as possible to the one or more light sources 508 without contacting the one or more light sources 508. In some embodiments, a gap 536 exists between the extension member 532 and the one or more light sources 508 to ensure that the extension member 532 does not contact the one or more light sources 508, and in turn cause an electrical short. The gap 536, in some embodiments, is in the range of 2 mm to equal to or greater than 20 mm, depending on the application. As can be seen, in some embodiments, the extension member 532 extends from one contact portion 528. In some embodiments, the extension member 532 extends from multiple different contact portions 528, depending on the application. In some embodiments, the extension member 532 extends along the PCB 504 so as not to interfere with the optic installed over the one or more light sources 508. In some such configurations, the extension member 532 extends beneath the optic installed over the one or more light sources 508. In some embodiments, the extension member 532 is made of the same material and includes a thickness substantially similar to that of the front heat sink 516, but this need not be the case in all instances. In some embodiments, the extension member 532 has a thickness of between 0.3 to 0.5 mm.

In some embodiments, the extension member 532 surrounds the one or more light sources 508 to receive thermal energy radiating from the one or more light sources 508 in different directions. As can be seen, the extension member 532 in some embodiments at least partially surrounds a group of the one or more light sources 508. Note that the extension member 532 here may not completely surround the group of the one or more light sources 508, but rather includes an opening through which the electrical traces extend therethrough. Furthermore, in some embodiments, the extension member 532 partially surrounds one group of the one or more light sources 508, as shown. However, the light module 500 of the present disclosure is not so limited. For example, in some embodiments, the extension member 532 partially surrounds multiple groups of the one or more light sources 508. In such embodiments, the extension member 532 is attached to the front heat sink 516 at one or more locations to provide additional support to the extension member 532. In some embodiments, the front heat sink 516 includes a plurality of extension members 532 that individually and separately surround discrete groups of the one or more light sources 508 disposed on the PCB 504 to transfer thermal energy to different portions of the front heat sink 516.

In some embodiments, the PCB 504 is configured to receive several light sources 508 that are constructed and arranged to generate light in a focused pattern. For instance, in some embodiments, an array of light sources 508 is arranged in a circular pattern, as shown. Other light source arrangements, such as grid patterns, are used depending on the number and size of the light sources 508 of the array. As shown in FIG. 5E, the PCB 504 includes an insulator 540 that defines multiple electrical traces 544A-G (collectively 544) within the PCB 504. The insulator 540 is made from electrically insulative or otherwise non-conductive materials so as to isolate the electrical traces 544 from one another. In some embodiments, the insulator 540 also electrically isolates the electrical traces 544 from the surrounding conductive layer 548 of the PCB 504.

The insulator 540 defines several electrical traces 544 that together enable the one or more light sources 508 disposed thereon to be electrically connected to a source of electrical power. To this end, the electrical traces 544 are configured to contact electrical connections of the one or more light sources 508 when the one or more light sources 508 are positioned on or otherwise over the insulator 540. In some embodiments, the electrical traces 544 are positioned in series with each other to enable the one or more light sources 508 to be positioned as close to one another as possible along the PCB 504 so as to not significantly reduce the size and thermal characteristics of the conductive layer 548 on the PCB 504.

Adjacent to the insulator 540 and within the conductive layer 548 are a plurality of thermal vias 552, which receive thermal energy from the one or more light sources 508. The plurality of thermal vias 552 are constructed and arranged to contact at least one thermal contact (e.g., a thermal pad) of the one or more light sources 508 to transfer thermal energy from the one or more light sources 508 to the rear heat sink 512. As can be seen, in some embodiments, the plurality of thermal vias 552 are located adjacent to an intersection or junction of two electrical traces 544, but this need not be the case in all embodiments. Depending on the construction of the one or more light sources 508, the plurality of thermal vias 552 can be located anywhere along the perimeter of the insulator 540 so long as the plurality of thermal vias 552 remain electrically isolated from the electrical traces 544. As can be seen, in some embodiments, some of the plurality of thermal vias 552 are located internally as well as externally to the insulator 540, depending on the desired configuration of the one or more light sources 508. In some embodiments, the plurality of thermal vias 552 are arranged in groups or subgroups so that multiple vias 552 contact one or more of the one or more light sources 508 to transfer thermal energy therefrom.

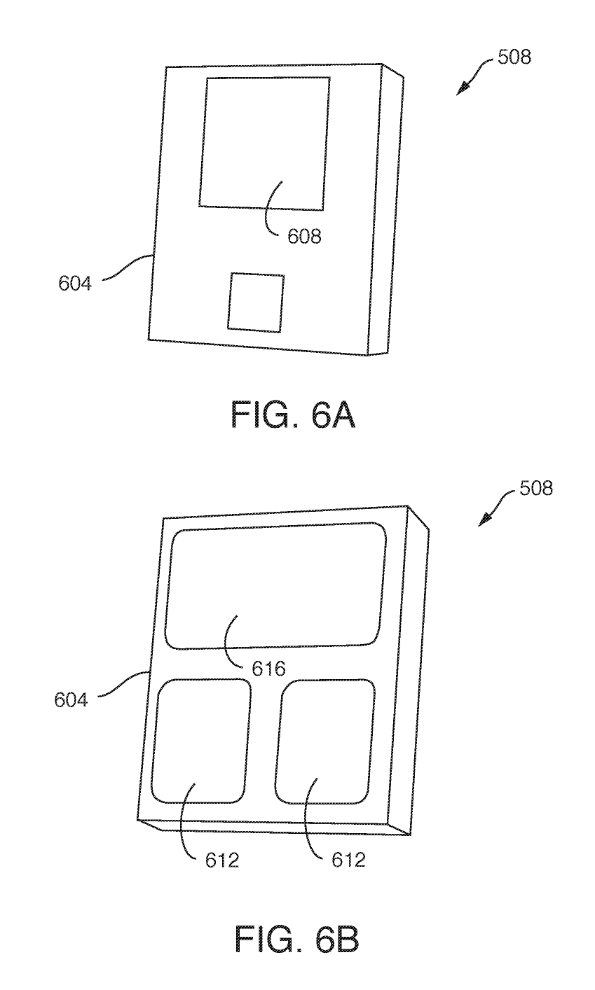

FIGS. 6A-6B are a front perspective view and a rear perspective view of one of the one or more light source 508 of the light module 500 shown in FIG. 5A. As can be seen, the light source 508 is similar to the light source 108 described above. The light source 508 includes a base 604, a semiconductor die 608, electrical contacts 612, and a thermal contact 616. The base 604, the semiconductor die 608, the electrical contacts 612, and the thermal contact 616 are similar to those previously described in relation to FIGS. 3A and 3B. Note that here the base 604 includes one thermal contact 616 in the form of a pad. The thermal contact 616 is configured to contact the plurality of thermal vias 552 in the PCB 504 to form a pathway, in which thermal energy may flow from the light source 508 to the rear heat sink 512. In particular, when the light source 508 is disposed onto or otherwise placed in contact with a pair of electrical traces 544 of the PCB 504, the thermal contact 616 is configured to contact thermal vias 552 adjacent to the junction between the pair of electrical traces 544. Numerous other light source configurations will be apparent in light of the present disclosure.

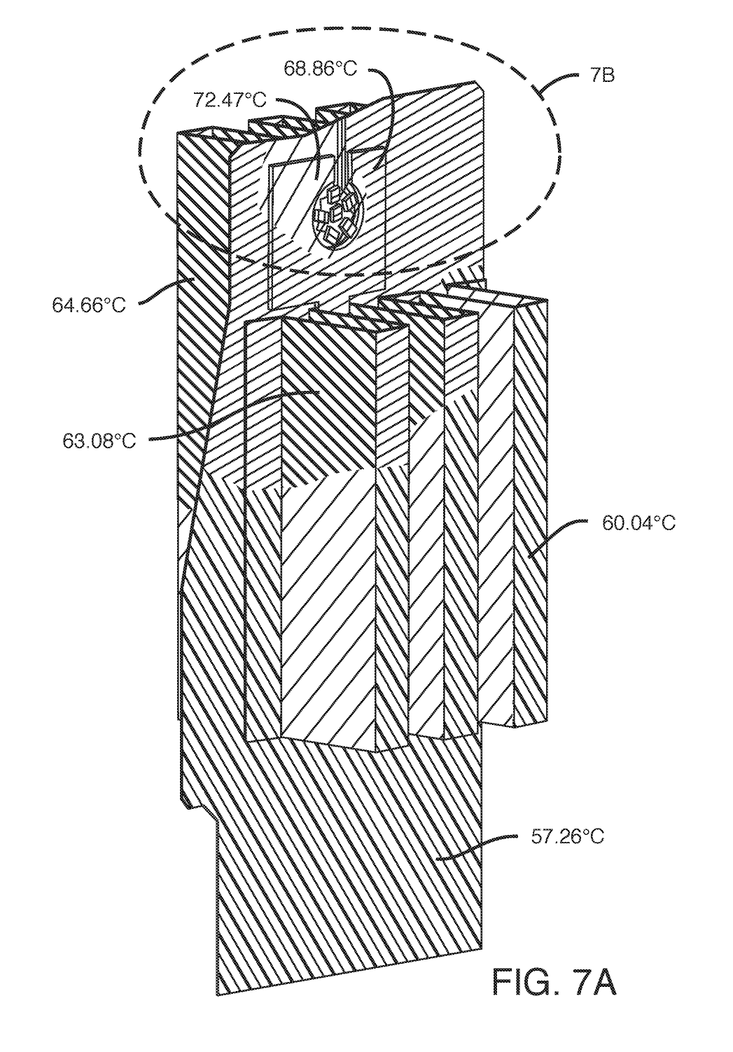

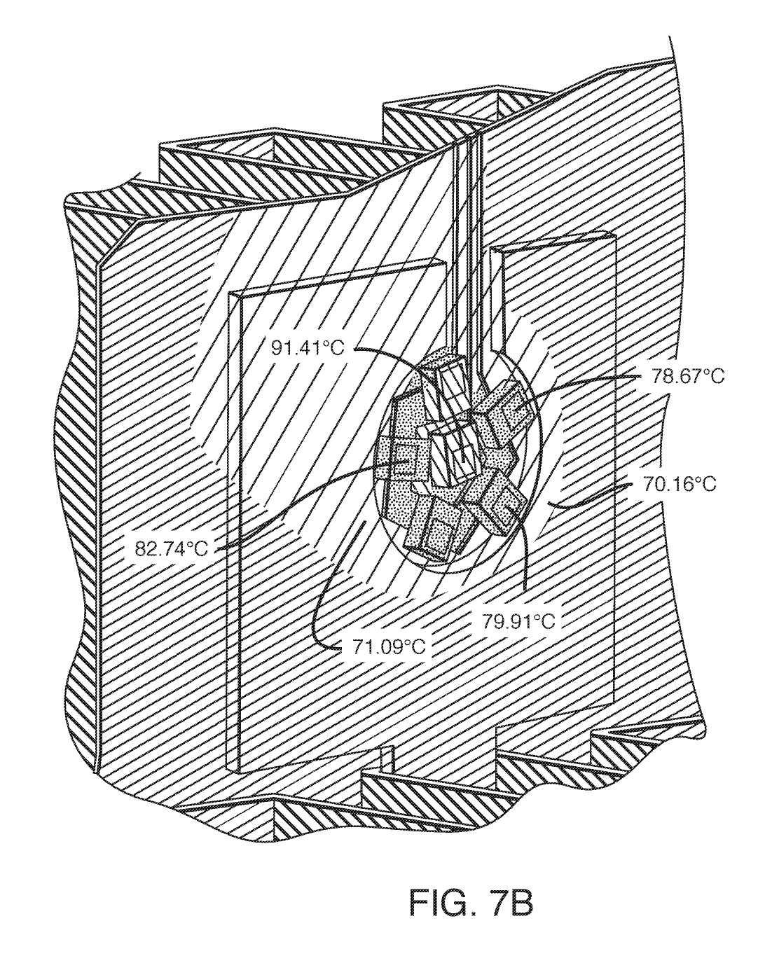

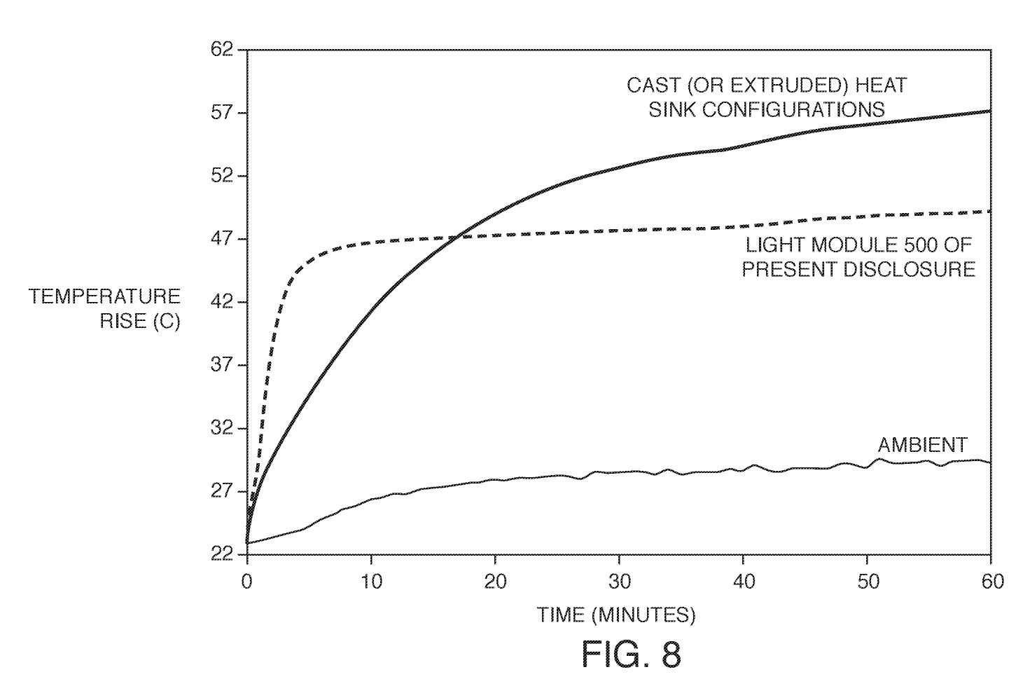

FIGS. 7A-7B illustrate temperature gradients within the light module 500 shown in FIGS. 5A-5E. FIG. 8 is a graph illustrating temperature versus time for the light module 500 of the present disclosure as compared with a previous heat sink design. In operation, the light modules of the present disclosure provide a light module that is lighter than cast or extruded heat sinks and configured to more effectively spread thermal energy throughout the heat sink than previous light weight designs that use multiple heat sinks. In particular, high brightness traditional light engines typically include cast or extruded heat sinks that provide sufficient thermal energy transfer, but are very heavy. The excessive weight of such heat sinks is undesirable in many applications, including automotive lighting applications. In an effort to reduce heat sink weight, other designs include FR-4 PCBs with multiple small heat sinks. However, these designs do not adequately spread the thermal energy to the heat sinks to cool the light sources. Particularly, in such cases, the light sources often experience temperatures above a desired temperature range in which to operate the light source, because thermal energy does not spread to the heat sinks located away from the light source. In other words, the thermal energy remains localized within the heat sink nearest the light source.

The light modules of the present disclosure address the above explained deficiencies of the traditional light engine designs. For instance, the light module 500, as described herein in relation to FIGS. 5A-5E, is significantly lighter than previous extruded or cast heat sink configurations. In addition, the light module 500 more effectively spreads thermal energy throughout the heat sinks than previous light weight, multiple heat sink designs. As evidenced by FIGS. 7A-7B, the thermal energy from the light sources can be distributed to both front and rear heat sinks. As can be seen, the thermal energy can be spread throughout the heat sinks to lower the temperature of the light sources. Thus, unlike previous light weight, multiple heat sink designs, the light modules of the present disclosure prevent an increase or buildup of thermal energy localized about the light sources. In some embodiments, the light module can experience a temperature gradient across the heat sinks of less than 15 degrees Celsius (C). In addition, the temperature of the light sources can be controlled using a front heat sink that includes an extension member. As shown in FIG. 7B, the light sources positioned near the extension member have a lower temperature than the light source at the center of the array of light sources. In some embodiments, the light sources adjacent to the extension member can be as much as 10 degrees C. cooler than other light sources of the light module (e.g., the light source at the center of the array).

Furthermore, in some embodiments, the light module 500 out performs light engines cooled using traditional cast or extruded heat sinks, as evidenced by the graph of FIG. 8. As shown by the graph, after 60 minutes one or more light sources cooled with the light module 500 are at a temperature that is significantly lower than the temperature of those one or more light sources cooled with the traditional aluminum heat sink. In particular, at the end of 60-minute test, the traditional heat sinks maintain the light sources at a temperature that can be 17% greater than that of light sources cooled using the light module 500. Furthermore, the light module 500 as described herein achieves a steady-state temperature faster, and with a lower saturated temperature, over time as compared to previous extruded or cast heat sink designs, in some embodiments, as evidenced by FIG. 8.

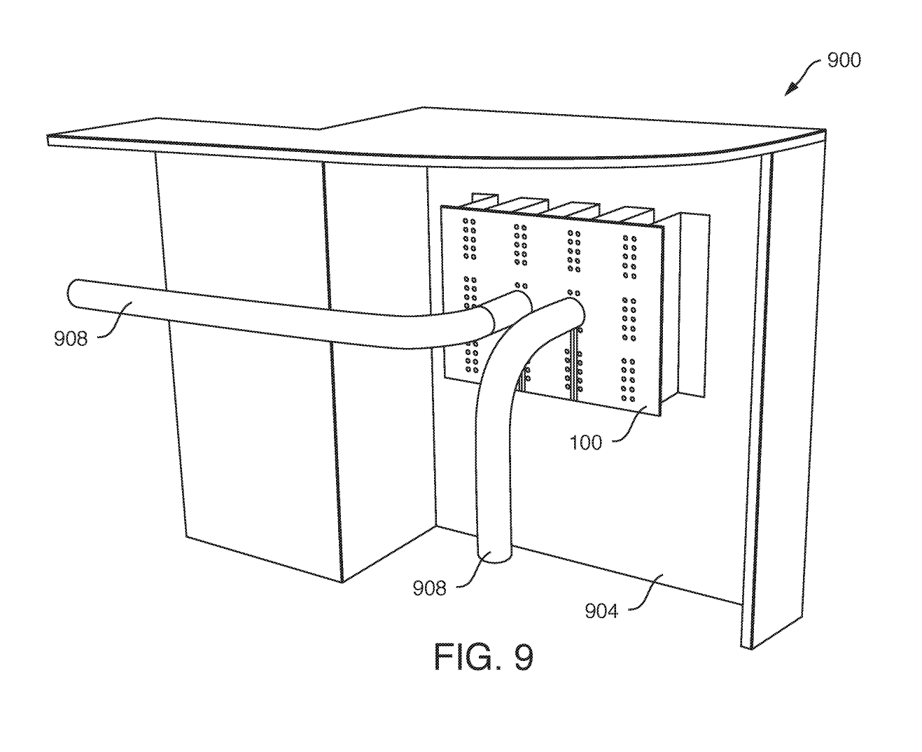

FIG. 9 illustrates a perspective view of a lighting device 900 that includes a light module 100. The light modules previously described herein may be used in combination with other components, such as optical devices, to form a lighting device, such as the lighting device 900. The lighting device 900 is used in a variety of applications, including but not limited to automotive applications. For instance, in such applications the lighting device 900 is a headlight, taillight, brake light, turn indicator, a day time running light, or an interior access light, just to name a few examples. The lighting device 900 of FIG. 9 includes a housing 904, a light module 100 (as described above), and an optic 908. In some embodiments, the lighting device 900 includes the light module 500 (as described above).

The housing 904 protects the light module 100 and the optic 908 from damage from external factors (e.g., debris) or/or environmental elements (e.g., rain). The housing 904, in some embodiments, is a sealed unit to prevent fluids, such as water, from entering the housing 904 and damaging the light module 100. The housing 904, in some embodiments, includes a cover lens (not shown) in a front portion of the housing 904 and bezels (not shown) around the optic 908 to hide or otherwise cover the light module 100 to create a desired look or aesthetic appearance of the lighting device 900. In some embodiments, the housing 904 houses or otherwise secures the light module 100 and the optic 908 in place. To this end, the housing 904 includes mounting means to receive the printed circuit board (PCB) 104 or the heat sink 112 (or both) of the light module 100. For example, in some embodiments the housing 904 includes fasteners (e.g. screws, bolts or rivets) that pass through the PCB 104 and the heat sink 112 of the light module 100. The additional material from the heat sink 112 provides for a more rigid connection between the light module 100 and the housing 904. This is particularly noteworthy in automotive applications, in which the light module 100 is likely to experience vibrations and impact forces (e.g., sudden shock) as the vehicle is driven.

The optic 908 disposed within the housing 904 is configured to beam shape (e.g., focus and direct) light generated by the light module 100. Generally speaking, the optic 908 is a device that manipulates electromagnetic radiation. For example, in some embodiments the optic 908 is a light pipe or tube (as shown) constructed and arranged to transmit or distribute light to illuminate an area. In some embodiments, the optic 908 is a reflector. No matter the type of optic used, the location of the optic 908 relative to the one or more light sources 108 of the light module 100 is important to operation of the lighting device 900, and in particular is critical in automotive head lamp applications. For example, in some embodiments the optic 908 is installed onto the PCB 104 using a fastener (e.g., a pin, screw, or bolt) that passes through or otherwise engages both the PCB 104 and the heat sink 112. The fastener may be more substantial in size, and thus provide a more stable optic installation, because the heat sink 112 supports some of the load from the fastener. In addition, more torque can be applied to the fastener, and in turn the fastener may more securely mount the optic 908 to the light module 100 because the fastener engages both the PCB 104 and the heat sink 112, and not just the PCB 104 alone. Thus, the optic 908 maintains its location relative to the one or more light sources 108 of the light module 100 to provide more consistent lighting performance over the course of the operating life of the lighting device 900.

Numerous other light module and light assembly embodiments will be apparent in light of the present disclosure. For instance, in some embodiments, the light module includes a plurality of heat sinks attached to either the front or back side of the printed circuit board (or both). In such embodiments, the printed circuit board may include one or more common soldering pads that can be used to join the heat sinks together and/or onto the printed circuit board. To this end, the printed circuit board may include soldering pads located along perimeter edges of the board to thermally connect the heat sinks to one another. In other embodiments, the soldering pads are located just along edges of the circuit board that are parallel with a longitudinal axis of the board.

Furthermore, the configuration the heat sinks of embodiments varies based on other factors besides the power associated with the light sources of the light module. In particular, the configuration of the heat sink may vary to accommodate particular manufacturing processes. For example, the heat sink can be manufactured from one or more copper alloys, and then subsequently tinned. The tinned outer coating of the heat sink allows it to be soldered directly to the printed circuit board using an automated pick-and-place process.

Unless otherwise stated, use of the word “substantially” may be construed to include a precise relationship, condition, arrangement, orientation, and/or other characteristic, and deviations thereof as understood by one of ordinary skill in the art, to the extent that such deviations do not materially affect the disclosed methods and systems.

Throughout the entirety of the present disclosure, use of the articles “a” and/or “an” and/or “the” to modify a noun may be understood to be used for convenience and to include one, or more than one, of the modified noun, unless otherwise specifically stated. The terms “comprising”, “including” and “having” are intended to be inclusive and mean that there may be additional elements other than the listed elements.

Elements, components, modules, and/or parts thereof that are described and/or otherwise portrayed through the figures to communicate with, be associated with, and/or be based on, something else, may be understood to so communicate, be associated with, and or be based on in a direct and/or indirect manner, unless otherwise stipulated herein.

Although the methods and systems have been described relative to a specific embodiment thereof, they are not so limited. Obviously many modifications and variations may become apparent in light of the above teachings. Many additional changes in the details, materials, and arrangement of parts, herein described and illustrated, may be made by those skilled in the art.

What is claimed is:

1. A lighting module comprising:
a printed circuit board comprising an insulative core, wherein the insulative core comprises a first side, a second side, and a plurality of thermal vias, wherein each of the first side and the second side of the insulative core comprise a thermally-conductive layer disposed thereon, and wherein the plurality of thermal vias are within the insulative core and in thermal contact with the respective thermally-conductive layers on the first side and the second side;
a light source attached to the thermally-conductive layer on the first side of the insulative core, wherein the light source is in thermal contact with at least one of the plurality of thermal vias, and wherein the light source is in electrical contact with electrical circuitry that is electrically isolated from the thermally-conductive layers; and
a heat sink attached to the thermally-conductive layer on the second side of the insulative core and in thermal contact with the plurality of thermal vias so that the light source transfers thermal energy to the heat sink but remains electrically isolated from the heat sink.

2. The lighting module of claim 1, wherein the heat sink is constructed and arranged as a single unitary piece, and wherein the heat sink exhibits a thermal conductivity of at least 300 W/m-K.

3. The lighting module of claim 1, wherein the light source is one of a plurality of light sources that are in thermal contact with at least one of the plurality of thermal vias, and wherein the light sources are in electrical contact with electrical circuitry that is electrically isolated from the thermally-conductive layers.

4. The lighting module of claim 1, wherein the light source comprises one or more solid state light sources, the one or more solid state light sources comprising a thermal contact and an electrical contact, wherein the thermal contact is isolated from the electrical contact and is in thermal communication with at least one semiconductor die.

5. The lighting module of claim 4, wherein the one or more solid state light sources each comprise a base, the base comprising a non-conductive material that electrically isolates the thermal contact from the electrical contact.

6. The lighting module of claim 1, wherein the heat sink comprises a major surface, and wherein the major surface is soldered directly to the thermally-conductive layer on the second side of the insulative core.

7. The lighting module of claim 1, wherein the heat sink comprises a plurality of folds so that a flat surface of the heat sink is located opposite the light source.

8. The lighting module of claim 1, wherein the heat sink comprises a plurality of fins, wherein at least one fin in the plurality of fins has a cross sectional shape that is a quadrilateral.

9. The lighting module of claim 1, wherein the heat sink comprises a plurality of fins, wherein at least one fin in the plurality of fins has a cross sectional shape comprising at least one edge that is a sinusoid or that includes a curve.

10. The lighting module of claim 1, wherein the heat sink is a first heat sink, the lighting module further comprising a second heat sink comprising a major surface, wherein the major surface of the second heat sink is attached to the thermally-conductive layer on first side of the insulative core.

11. The lighting module of claim 10, wherein the second heat sink comprises an extension member, wherein the extension member is attached to an end of the second heat sink and extends to a portion of the printed circuit board that includes the light source.

12. The lighting module of claim 11, wherein the first heat sink and the second heat sink comprise copper alloys.

13. The lighting module of claim 1, wherein the insulative core comprises a glass-reinforced epoxy laminate material.

14. The lighting module of claim 1, wherein the heat sink comprises a plurality of fins, wherein the fins in the plurality of fins extend along the heat sink in a direction along the printed circuit board so as to stiffen the printed circuit board to prevent bending of the printed circuit board along an axis in that direction.

15. The lighting module of claim 1, wherein the printed circuit board comprises a thickness in the range of 0.1 mm to 0.75 mm, the thickness including each of the thermally-conductive layers and the insulative core.

16. A lighting device, comprising:
a housing;
a lighting module disposed within the housing, the lighting module comprising:
a printed circuit board comprising an insulative core, wherein the insulative core comprises a first side, a second side, and a plurality of thermal vias, wherein each of the first side and the second side of the insulative core comprise a thermally-conductive layer disposed thereon, and wherein the plurality of thermal vias are within the insulative core and in thermal contact with the respective thermally-conductive layers on the first side and the second side;
at least one light sources attached to the thermally-conductive layer on the first side of the insulative core, wherein the at least one light source is in thermal contact with at least one of the plurality of thermal vias and is in electrical contact with electrical circuitry that is electrically isolated from the thermally-conductive layers; and
a heat sink attached to the thermally-conductive layer on the second side of the insulative core and in thermal contact with the plurality of thermal vias so that the at least one light source transfers thermal energy to the heat sink but remains electrically isolated from the heat sink; and
an optic disposed within the housing, the optic configured to beam shape light emitted from the lighting module.

17. The lighting device of claim 16, wherein the heat sink comprises a copper alloy, wherein the heat sink comprises an exterior coating on at least one major surface, and wherein the exterior coating comprises a tin alloy.

18. The lighting device of claim 16, wherein the heat sink is a first heat sink, and the lighting module further comprises a second heat sink, wherein the second heat sink is attached to the thermally-conductive layer on the first side of the insulative core.

19. The lighting device of claim 16, wherein the at least one light source comprises a plurality of solid state light sources, wherein the plurality of solid state light sources comprises one of light emitting diodes, laser light sources, and light emitting diodes and laser light sources.

20. A vehicle comprising the lighting device of claim 16.
